(19) United States
(12) Patent Application Publication
(10) Pub. No.: US 2026/0039259 A1
(43) Pub. Date: Feb. 5, 2026

(54) HIGH POWER RADIO FREQUENCY CASCODE DEVICE

(71) Applicant: MACOM Technology Solutions Holdings, Inc., Lowell, MA (US)

(72) Inventors: Marvin Marbell, Cary, NC (US); Walter H. Nagy, Raleigh, NC (US); Wayne Mack Struble, Franklin, MA (US); Jeremy Keith Fisher, Raleigh, NC (US); Bradley Millon, Durham, NC (US); Simon Maurice Wood, Morgan Hill, CA (US)

(21) Appl. No.: 18/792,757

(22) Filed: Aug. 2, 2024

(51) Int. Cl. H03F 3/193; H03F 1/22; H03F 3/45

(52) U.S. Cl. CPC H03F 3/193; H03F 1/223; H03F 3/45; H03F 2200/451; H03F 2203/45

(57) ABSTRACT

A cascode amplifier circuit includes a first transistor connected in a common-source configuration, and a second transistor connected in a common-gate configuration. The first transistor includes a gate for receiving a radio frequency (RF) input signal. The second transistor includes a first source/drain for delivering an RF output signal of the cascode amplifier circuit, a second source/drain connected to a first source/drain of the first transistor, and a gate for receiving a portion of the RF input signal.

### FIELD

The present disclosure relates generally to radio frequency (RF) amplifiers, and, more particularly, to high power RF cascode devices having enhanced stability and performance at high frequencies.

### BACKGROUND

Electrical circuits requiring high power handling capability while operating at high frequencies, such as, for example, frequencies greater than about 500 MHz, have become increasing more prevalent, particularly in cellular communications applications. There currently is demand for semiconductor devices which are capable of both reliably and efficiently operating at radio frequencies (including microwave and millimeter wave frequencies) while still being capable of handling high voltage swings.

RF power amplifiers using a cascode arrangement of transistors are widely used in communication systems for handling the high power needed for wireless communications. In a cascode arrangement, an RF input signal is fed to the gate of a first transistor (the common-source device) and an amplified RF output signal is delivered to an output lead of a second transistor (the cascode device, which may also be referred to herein as the common-gate device) connected with the first transistor in a cascode arrangement. This arrangement enables the cascode device to be operated at a higher voltage (e.g., twice) compared to a single common-source device. However, when the operating frequency is high relative to a parasitic gate-source capacitance of the cascode device, and the gate of the common-gate device is terminating to a good RF ground, then some of the RF current from the common-source device will be diverted through the gate-source capacitance of the cascode device and dissipated to ground. Therefore, there is a loss of power and efficiency using a standard cascode arrangement.

### SUMMARY

The present invention, as manifested in one or more embodiments, provides a high power RF cascode device having enhanced stability and performance at high frequencies (e.g., S-band, C-band, and/or X-band). To achieve this, embodiments of the inventive concept provide an amplifier circuit in which a portion (e.g., 5%, 10%, 20%, 50%, etc.) of an RF input signal supplied to the amplifier circuit is split and fed to the gate of a common-gate transistor to establish the voltage at the input of the common-gate transistor, while the remaining portion of the RF input signal is fed to the gate of a common-source device connected in a cascode configuration with the common-gate device. Compared to conventional amplifier implementations which feed all of the RF input signal to the gate of the common-source transistor, embodiments of the present invention allow for a better trade-off between stability and performance of the cascode amplifier circuit. In this manner, improved performance (e.g., gain, efficiency and peak power) can be achieved with similar stability as compared to standard amplifier designs, or enhanced stability can be achieved with similar performance (e.g., gain, efficiency and peak power) compared to standard amplifier designs.

In accordance with an embodiment of the present disclosure, a cascode amplifier circuit includes a first transistor connected in a common-source configuration, and a second transistor connected in a common-gate configuration. The first transistor includes a gate for receiving an RF input signal. The second transistor includes a first source/drain for delivering an RF output signal of the cascode amplifier circuit, a second source/drain connected to a first source/drain of the first transistor, and a gate for receiving a portion of the RF input signal. The amplifier circuit may include an input power coupler connected to the gate of the first transistor, the input power coupler being configured to feed a portion of the RF input signal provided to the second transistor.

In accordance with another embodiment of the present disclosure, a cascode amplifier circuit includes: a first transistor including a first source/drain connected to ground, a gate connected to an input terminal, and a second source/drain; and a second transistor including a first source/drain connected to the second source/drain of the first transistor, a second source/drain connected to an output terminal, and a gate. The amplifier circuit further includes a first capacitor connected between the second source/drain and gate of the second transistor, and a second capacitor connected between the gate of the second transistor and the gate of the first transistor. The gate of the second transistor is coupled to ground through a series resistor-capacitor network. In some embodiments, the series RC network may include a first resistor having a first terminal connected to ground, and a third capacitor having a first terminal connected to the gate of the second transistor and a second terminal connected to a second terminal of the first resistor.

In accordance with yet another embodiment of the present disclosure, a cascode amplifier circuit includes: a first transistor including a first source/drain connected to ground, a gate connected to an input terminal, and a second source/drain; a second transistor including a first source/drain connected to the second source/drain of the first transistor, a second source/drain connected to an output terminal, and a gate; a power coupler having an input port connected to the input terminal, a first output port connected to the gate of the first transistor, and a second output port connected to the gate of the second transistor, the power coupler being configured to provide a first signal at the first output port and a second signal at the second output port, the first and second signals being respective portions of an input signal present at the input port; and an auxiliary amplifier having an input connected to the second output port of the power coupler and having an output connected to the gate of the second transistor. In some embodiments, the auxiliary amplifier includes a third transistor including a first source/drain connected to ground, a gate connected to the second output port of the power coupler, and a second source/drain, and a fourth transistor including a first source/drain connected to the second source/drain of the third transistor, a second source/drain connected to the gate of the second transistor, and a gate connected to ground.

In accordance with one or more embodiments of the present disclosure, a cascode amplifier circuit includes a first transistor including a first source/drain connected to ground, a gate connected to an input terminal, and a second source/drain, and a second transistor including a first source/drain connected to the second source/drain of the first transistor, a second source/drain connected to an output terminal, and a gate. The amplifier circuit further includes a differential power coupler including a differential input port, a first differential output port connected between the gate of the first transistor and ground, and a second differential output port connected between the gate and first source/drain of the second transistor. In some embodiments, the differential power coupler is configured to provide a first differential signal at the first differential output port and a second differential signal at the second differential output port, the first and second differential signals being respective portions of an input signal present at the differential input port.

Techniques of the present inventive concept can provide substantial beneficial technical effects. By way of example only and without limitation, aspects according to embodiments of the present disclosure may provide one or more of the following advantages, among other benefits:
the RF cascode amplifiers having improved performance (e.g., gain, efficiency and peak power) can be achieved with similar stability as compared to standard cascode amplifier designs, or enhanced stability can be achieved with similar performance (e.g., gain, efficiency and peak power) compared to standard cascode amplifier designs;
the magnitude and/or phase of the portion of the RF input signal that is coupled to the gate of the common-gate transistor can be dynamically adjusted to improve the trade-off between performance and stability without having to fabricate new devices (e.g., by generating a new tape-out) with a specific implementation;
the RF cascode amplifiers can be integrated on a single chip using the same fabrication process technology as standard cascode transistor implementations, with little change to the overall chip size and cost;
can be implemented on an individual finger or cell level so that multiple fingers or cells can be aggregated together for achieving high power at high frequency with enhanced functionality;
multiple common-gate stages (e.g., two common-gate stages with one common-source stage) can be stacked to achieve higher voltage without degrading stability.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a schematic circuit diagram depicting an illustrative power RF cascode amplifier circuit;

FIG. 2A is a schematic circuit diagram depicting at least a portion of an example power RF cascode amplifier circuit topology utilizing passive voltage reconstruction, according to one or more embodiments of the present invention;

FIG. 2B is a schematic plan view of an illustrative layout of the power RF cascode amplifier circuit shown in FIG. 2A;

FIG. 3A is a more detailed circuit diagram of the power RF cascode amplifier circuit shown in FIG. 2A;

FIG. 3B is a schematic plan view of an illustrative layout of the power RF cascode amplifier circuit shown in FIG. 3A;

FIG. 4 is a schematic circuit diagram conceptually depicting at least a portion of an example power RF cascode amplifier circuit topology utilizing active voltage reconstruction, according to one or more embodiments of the present invention;

FIG. 5A is a more detailed circuit diagram of one example implementation of the power RF cascode amplifier circuit of FIG. 4

FIG. 5B is a schematic plan view of an illustrative layout of the power RF cascode amplifier circuit shown in FIG. 5A;

FIG. 5C is a more detailed circuit of another example implementation of the power RF cascode amplifier circuit of FIG. 4;

FIG. 6A is a schematic circuit diagram conceptually depicting at least a portion of an example power RF cascode amplifier circuit utilizing a power input coupler with independent grounds, according to one or more embodiments of the present invention;

FIG. 6B is a more detailed circuit diagram of the power RF cascode amplifier circuit of FIG. 6A; and

FIG. 6C is a schematic plan view of an illustrative layout of the power RF cascode amplifier circuit shown in FIG. 6B.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in one or more embodiments, may be described herein in the context of RF power amplifier circuits and devices, and more specifically to embodiments of a high power RF cascode amplifier having enhanced reliability and performance at high frequencies (e.g., S-band, C-band, and/or X-band), which may be suitable for use in a wireless communications environment, among other beneficial applications. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of embodiments of the claimed invention. That is, no limitations with respect to the embodiments shown and described herein are intended or should be inferred.

In some embodiments, the RF power amplifiers may be configured to operate at frequencies greater than 1 GHz. In other embodiments, these RF power amplifiers may be configured to operate at frequencies greater than 2.5 GHZ. In still other embodiments, the RF power amplifiers may be configured to operate at frequencies greater than 3.1 GHz. In yet additional embodiments, these RF power amplifiers may be configured to operate at frequencies greater than 5 GHz. By way of example only and without limitation, RF power amplifiers according to embodiments of the present invention may be designed to operate in a wide variety of different frequency bands, such as, for example, S-band (2-4 GHZ), C-band (4-8 GHZ) and/or X-band (8-12 GHZ).

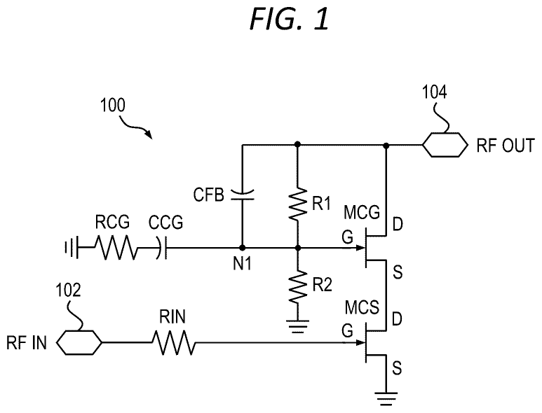

FIG. 1 is a schematic circuit diagram depicting a power RF cascode amplifier circuit 100. The amplifier circuit 100 includes a first transistor (common-source device), MCS, connected in a common-source configuration, and a second transistor (common-gate device), MCG, connected in a common-gate configuration. The first and second transistors MCS, MCG may be gallium nitride (GaN) high-electron-mobility transistors (HEMTs), also known as heterostructure field-effect transistors (HFETs), on silicon carbide (SiC) or silicon substrates, although power n-channel (i.e., n-type) metal-oxide-semiconductor (NMOS) field-effect transistors (FETs) may be used in some embodiments. The first transistor MCS includes a source(S) connected to a voltage return, which may be ground, a gate (G) adapted to receive an RF input signal, RF IN, through a first resistor, RIN, and a drain (D) connected to a source of the second transistor MCG. The RF input signal RF IN may be supplied at a first terminal 102 of the RF cascode amplifier circuit 100. The second transistor MCG further includes a gate connected to a first node N1, and a drain for delivering an RF output signal, RF OUT, to a second terminal 104 of the amplifier circuit 100.

A first (feedback) capacitor, CFB, may be connected in a feedback configuration between the gate (at node N1) and the drain of the second transistor MCG. A second capacitor, CCG, may be connected between the gate of the second transistor MCG (at node N1) and ground through a second resistor, RCG. The second capacitor CCG and second resistor RCG form a series resistor-capacitor (RC) network.

During operation of the amplifier circuit 100, a large voltage swing may appear at the drain of the common-source device MCS. For example, with the common-gate device MCG operating at 100 V drain voltage, the common-source device MCS may experience a voltage swing of, for example, 52 V±45 V at its drain. The voltage across the gate and source of the common-gate device MCG should be limited (e.g., to about −2 V±2 V) to prevent a gate diode of the common-gate device MCG from becoming forward-biased. In order to satisfy Kirchoff's and Ohm's Laws, a large voltage swing must also be established at the gate of the common-gate device MCG, so that the gate-to-source voltage of the common-gate device MCG, which is equal to the gate voltage of the common-gate device MCG minus the drain voltage of the common-source device MCS, remains less than about −2 V±2 V. This large voltage swing on the gate of the common-gate device MCG is present due to a voltage divider between the drain of the common-gate device MCG and ground. The voltage divider may be implemented, for example, using a first resistor, R1, connected between the drain and gate of the common-gate device MCG and a second resistor R2, connected between the gate of the common-gate device MCG and ground. In one or more embodiments, resistance values of the first and second resistors R1, R2 may be sufficiently high (e.g., about 10K-100K ohms) so as to minimize current flow and efficiency loss through them.

When the operating frequency is high relative to a parasitic gate-to-source capacitance of the common-gate device MCG, then some of the RF current originating from the common-source device MCS will be diverted through the gate-to-source capacitance of the common-gate device MCG and dissipated in the second resistor RCG to ground. The RF signal diverted through the gate-to-source capacitance of the common-gate device MCG will never reach the RF output terminal 104, and therefore this diverted RF signal is exhibited as a loss of power and efficiency in the amplifier circuit 100. Additionally, a relatively small capacitance value is needed for the second capacitor CCG in order to create a high impedance for preventing RF current from leaking through the parasitic gate-to-source capacitance of the common-gate device MCG, but this high impedance creates a poor RF ground, thereby degrading performance of the common-gate device MCG. Decreasing the value of the second capacitor CCG will degrade the RF ground at the expense of reducing output power and efficiency of the amplifier circuit 100. Stated differently, a higher parasitic gate-to-source capacitance of the common-gate device MCG may make it harder to establish a proper RF voltage across the gate-source of the common-gate device MCG, and if the proper RF voltage is not established, then performance will degrade.

The feedback capacitor CFB can be used to keep the common-gate device MCG stable while helping to generate the gate voltage for the common-gate device MCG by coupling a portion of the RF output voltage RF OUT from the output terminal 104 to the gate of the common-gate device MCG. However, this will further increase RF power loss and decrease efficiency in the amplifier circuit 100.

Pursuant to embodiments of the present invention, high-power RF cascode devices are provided for use in an RF power amplifier application having improved stability and performance at high frequencies (e.g., S-band, C-band, and/or X-band) while reducing the loss of power and efficiency that other cascode amplifier circuits exhibit. In one or more embodiments, a portion (e.g., 5%, 10%, 20%, 50%, etc.) of the RF input signal may be coupled and fed to the gate of the common-gate transistor to establish the voltage at the input of the common-gate transistor. It is to be understood that there is no theoretical minimum amount of the RF input signal fed to the gate of the common-gate device for embodiments of the inventive concept to achieve some benefit over conventional RF power amplifiers; that is, any amount of intentional coupling (i.e., greater than zero percent) of the RF input signal fed to the gate of the common-gate device may achieve some measurable benefit. Compared to conventional amplifier implementations which feed all (i.e., 100%) of the RF input signal to the gate of the common-source transistor, embodiments of the present invention allow for a better trade-off between stability and performance of the cascode amplifier circuit. In this manner, improved performance (e.g., gain, efficiency and peak power) can be achieved with similar stability as compared to standard amplifier designs, or enhanced stability can be achieved with similar performance (e.g., gain, efficiency and peak power) compared to standard amplifier designs.

The coupled RF input signal may be transformed to a prescribed voltage level and phase using passive elements, such as, for example, transmission lines, inductors, capacitors, etc., or it can be fed to an auxiliary amplifier before being supplied to the gate of the cascode transistor. The auxiliary amplifier may be formed as a small portion (e.g., 10% or 20%) of the periphery of the main cascode transistor (e.g., when the cascode transistor is formed using multiple finger or cells) and may be integrated onto the same chip as the cascode transistor, or it may be a separate transistor attached in the same package or an external amplifier on a parent circuit board. The auxiliary amplifier may be configured as a common-source transistor or as a miniaturized cascode transistor. Additionally, the coupled RF input signal may be fed as a single-ended (i.e., unbalanced) or differential (i.e., balanced) signal with respect to the source of the cascode transistor.

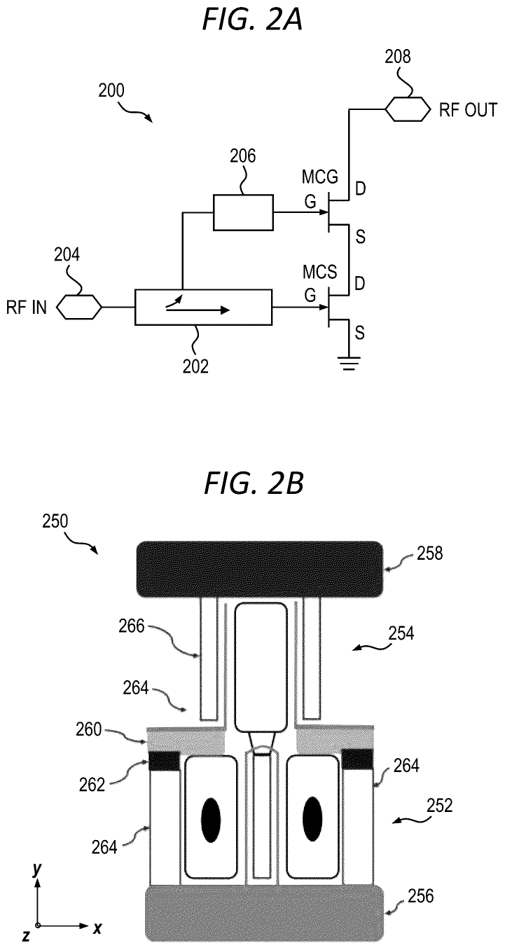

FIG. 2A is a schematic diagram depicting at least a portion of an example topology for a power RF cascode amplifier circuit 200 utilizing passive voltage reconstruction, according to one or more embodiments. Referring to FIG. 2A, the amplifier circuit 200 includes a first transistor (i.e., common-source device), MCS, connected in a common-source configuration, and a second transistor (i.e., common-gate), MCG, connected in a common-gate configuration. Each of the first and second transistors MCS, MCG may be a GaN HEMT on a SiC or silicon substrate, although embodiments are not limited thereto. For high voltage devices (e.g., 28V, 50V, etc.), gate-drain spacing is typically longer than gate-source spacing, and a field plate may also be provided between the gate and drain to minimize the high electric fields in the device.

The first transistor MCS includes a source(S) connected to a voltage return, which may be ground, a gate (G) adapted to receive an RF input signal, RF IN, through an input power coupler (i.e., power divider or power splitter) 202, and a drain (D) connected to a source of the second transistor MCG. The RF input signal RF IN may be supplied at a first terminal 204 of the amplifier circuit 200. The input power coupler 202 may be configured such that a portion of the RF input signal RF IN supplied to an input port of the input power coupler 202 passes through the input power coupler 202 and fed to the gate of the common-source device MCS and some of the RF input signal RF IN is coupled off and fed to the gate of the common-gate device MCG. The second transistor MCG further includes a gate connected to an impedance/voltage transform network 206, and a drain for delivering an RF output signal, RF OUT, to a second terminal 208 of the amplifier circuit 200. The common-source device MCS and the common-gate device MCG, integrated together in the manner shown, may be considered a cascode device.

The input power coupler 202 may be configured to couple a prescribed percentage of the RF input signal RF IN to the common-gate device MCG. For example, the input power coupler 202 may be configured to couple 10% (−10 dB), 20% (−7 dB), or 50% (−3 dB) of the RF input signal RF IN to the common-gate device MCG. In one or more embodiments, the input power coupler 202 may be implemented as a power divider network, coupled line coupler, or a proportionally sized division of the first terminal 204, which may be a gate pad of the common-source device MCS, although embodiments are not limited thereto.

The impedance/voltage transform network 206 may be configured to transform the coupled RF input signal supplied by the input power coupler 202 to an appropriate voltage level, impedance and/or phase, and to deliver the transformed signal to the gate of the common-gate device MCG. The term “and/or,” as may be used herein, is intended to include any and all combinations of one or more of the associated listed items. The impedance/voltage transform network 206 may be implemented using passive elements, such as, for example, transmission lines, inductors, or capacitors, although embodiments are not limited thereto. Note, that although not explicitly shown in FIG. 2A, the common-gate input capacitor CCG shown in FIG. 1 may still be present, but supplemented by the presence of the impedance/voltage transform network 206 and the input power coupler 202.

By way of example only and without limitation, FIG. 2B is a schematic plan view of an illustrative layout 250 of the amplifier circuit 200 shown in FIG. 2A, according to one or more embodiments. Referring to FIG. 2B, the layout 250 conceptually depicts the common-source device (MCS in FIG. 2A) 252 and the common-gate device (MCG in FIG. 2A) 254 adjacent the common-source device 252 in a first horizontal direction (e.g., y-direction). The common-source device 252 and the common-gate device 254 may be formed as multiple-fingered devices of a combined cascode device. In some embodiments, each of the common-source device 252 and the common-gate device 254 may be formed of gallium nitride (GaN) and/or silicon carbide (SiC), although embodiments of the invention are not limited to such materials.

A gate of the common-source device 252 is connected to an input gate pad 256, which may be represented by the first terminal 204 of the amplifier circuit 200 shown in FIG. 2A. The input gate pad 256 may extend longitudinally in a second horizontal direction (e.g., x-direction) intersecting the first horizontal direction. A drain of the common-gate device 254 is connected to an output drain pad 258, which may be represented by the second terminal 208 of the amplifier circuit 200 shown in FIG. 2A. The output drain pad 258 may extend longitudinally in the second horizontal direction. Each of the input gate pad 256 and the output drain pad 258 may comprise metal (e.g., metallization layer). The common-source device 252 and the common-gate device 254 may be formed between the input gate pad 256 and the output drain pad 258 in the first horizontal direction.

The layout 250 includes an input match network capacitor 260 and an input match network resistor 262, which may be represented by the second capacitor CCG and second resistor RCG, respectively, in FIG. 1 and may be part of the impedance/voltage transform network 206 shown in FIG. 2A. Portions of the input match network capacitor 260 and the input match network resistor 262 may be formed on opposing sides of the common-gate device 254 in the second horizontal direction. An input match network 264, which may also be part of the impedance/voltage transform network 206 shown in FIG. 2A, may also be formed on opposing sides of the common-source device 252 and the common-gate device 254 in the second horizontal direction. The input match network 264 may be electrically and physically interposed between the input gate pad 256 and the gate of the common-gate device 254, thus implementing the function of both the input power coupler 202 and the impedance/voltage transform network 206 shown in FIG. 2A. In one or more embodiments, the input match network 264 may alternatively, or in addition to, be implemented using coupled transmission lines, inductors, capacitors, resistors, or other passive components. The layout 250 further illustrates multiple drain fingers 266 of the common-gate device 254 connected to the output drain pad 258.

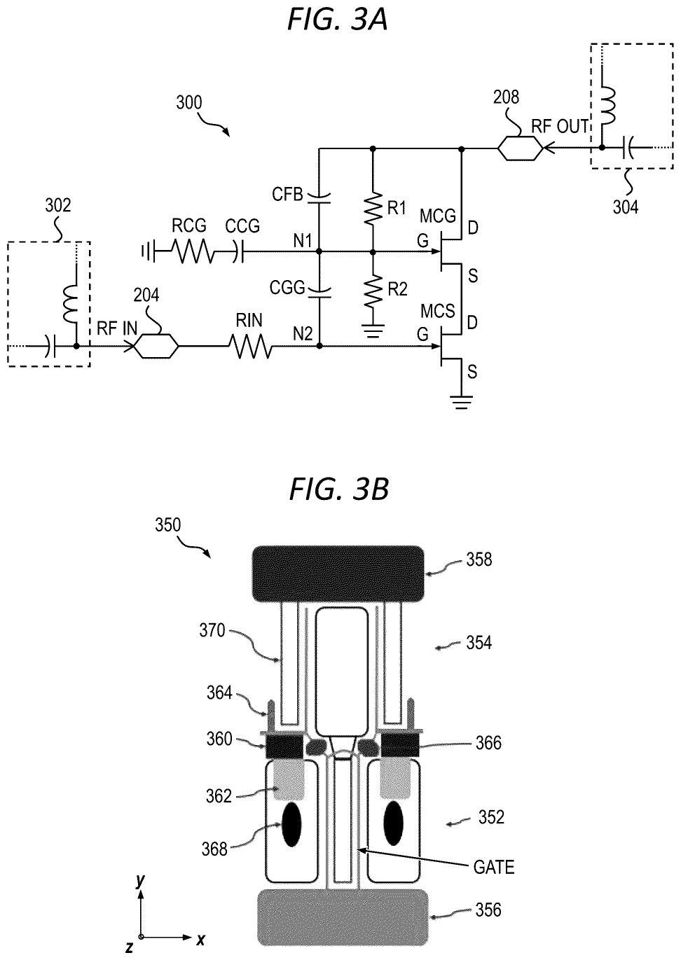

FIG. 3A is a schematic diagram depicting at least a portion of an example power RF cascode amplifier circuit 300, according to one or more embodiments. The amplifier circuit 300 may be considered one specific implementation of the conceptual amplifier circuit topology shown in FIG. 2A. Referring to FIG. 3A, the amplifier circuit 300 may be similar to the amplifier circuit 100 shown in FIG. 1, except for the addition of a third capacitor (i.e., common-gate ground input capacitor), CGG, coupled between the gate of the common-source device MCS at node N2 and the gate of the common-gate device MCG at node N1. Connected in this manner, the third capacitor CGG functions to couple a portion of the RF input signal RF IN present at the gate of the common-source device MCS to the gate of the common-gate device MCG. The amount of RF input signal coupled to the gate of the common-gate device MCG will be a function of the value of the third capacitor CGG. The third capacitor CGG implements the functions of both the input coupler 202 and the impedance/voltage transform network 206 shown in FIG. 2A and works as a simple, effective way to implement aspects of the inventive concept.

The amplifier circuit 300 includes a voltage divider network which may be used to bias the amplifier circuit 300. In one or more embodiments, the voltage divider network may be implemented, for example, using a first resistor, R1, connected between the drain and gate of the common-gate device MCG and a second resistor R2, connected between the gate of the common-gate device MCG and ground, although embodiments are not limited thereto. This voltage divider network may be integrated with the cascode device or it may be external to the cascode device. In other embodiments, there may be input and output DC bias networks 302 and 304, respectively, provided as part of an external printed circuit board (PCB) matching network. For example, each of the input DC bias network 302 and the output DC bias network 304 may comprise a quarter-wave line with DC blocking capacitors, or DC feed inductor with DC blocking capacitors, etc., connected to the RF input (at first terminal 204) and the RF output (at second terminal 208), respectively.

By way of example only and without limitation, FIG. 3B is a schematic plan view of an illustrative layout 350 of the amplifier circuit 300 shown in FIG. 3A, according to one or more embodiments. Referring to FIG. 3B, the layout 350 conceptually depicts the common-source device (MCS in FIG. 3A) 352 and the common-gate device (MCG in FIG. 3A) 354 adjacent the common-source device 352 in the first horizontal direction (y-direction). Each of the common-source device 352 and the common-gate device 354 may be formed as a multiple-fingered device.

A gate of the common-source device 352 is connected to an input gate pad 356, which may be represented by the first terminal 204 of the amplifier circuit 300 shown in FIG. 3A. The input gate pad 356 may extend longitudinally in the second horizontal direction (e.g., x-direction). Drain fingers 370 of the common-gate device 354 are connected to an output drain pad 358, which may be represented by the second terminal 208 of the amplifier circuit 300 shown in FIG. 3A. The output drain pad 358 may extend longitudinally in the second horizontal direction. Each of the input gate pad 356 and the output drain pad 358 may comprise metal (e.g., metallization layer). The common-source device 352 and the common-gate device 354 may be formed between the input gate pad 356 and the output drain pad 358 in the first horizontal direction.

The layout 350 includes a common-gate input capacitor 360 and a common-gate input resistor 362, which may be represented by the second capacitor CCG and second resistor RCG, respectively, in FIG. 3A. The common-gate input capacitor 360 may be formed on opposing sides of the common-sourced device 352 in the second horizontal direction. A common-gate feedback capacitor 364, which may be represented by the second capacitor CFB in FIG. 3A, may be formed on opposing sides of the common-gate device 354 in the second horizontal direction. A connecting gate capacitor 366, which may be represented by the third capacitor CGG in FIG. 3A, may be disposed between gate fingers of the common-source and common-gate devices 352, 354. The layout 350 further includes common-source device source vias 368 for electrically connecting the multiple source fingers of the common-source device 352 to ground. It is to be understood that the layout 350 may include additional features not shown in FIG. 3B for clarity. For example, the layout 350 may include field plate metal between the drain and gate lines, as well as other features that may be typically included in a SiC GaN HEMT device.

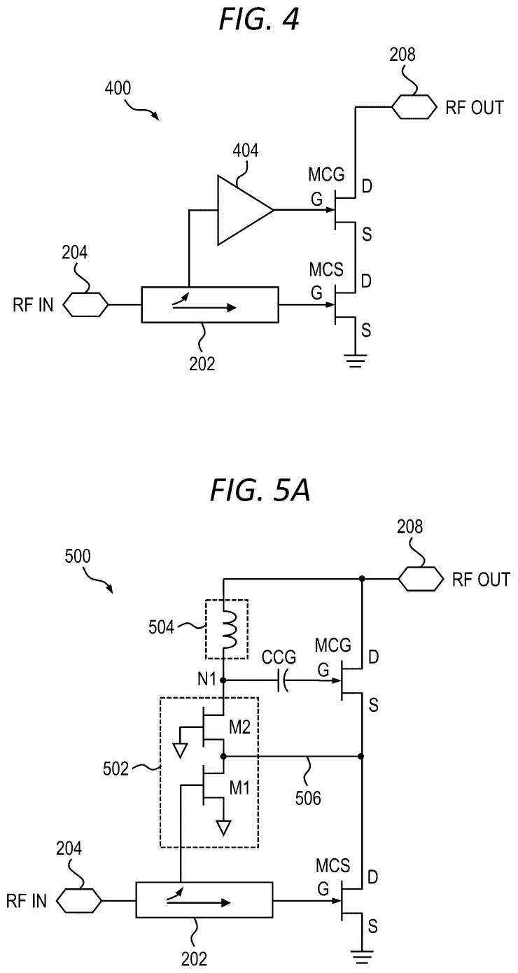

FIG. 4 is a schematic diagram depicting at least a portion of an example power RF cascode amplifier circuit 400 topology utilizing active voltage reconstruction, according to one or more embodiments. The amplifier circuit 400 may be similar to the illustrative amplifier circuit 200 shown in FIG. 2A, except that the passive impedance/voltage transform network 206 is replaced by an active component configured to provide active reconstruction of the gate voltage for the common-gate device MCG.

Referring to FIG. 4, the amplifier circuit 400 includes an auxiliary amplifier 404, which may be referred to as a reconstruction amplifier. Similar to the illustrative amplifier circuit 200 shown in FIG. 2A, a portion of the RF input signal RF IN may be coupled off using the input power coupler 202 and provided to the gate of the common-gate device MCG. However, rather than using a passive impedance/voltage transform network to condition the signal, the coupled RF input signal is provided to an input of the auxiliary amplifier 404 which is configured to condition the coupled RF input signal before feeding the conditioned input signal to the gate of the common-gate device MCG.

The auxiliary amplifier 404 may be implemented as a smaller periphery of the common-source device MCS (e.g., about 10% or 20%). In one or more embodiments, the auxiliary amplifier 404 may alternatively or additionally be implemented as a smaller periphery of the common-gate device MCG. The auxiliary amplifier 404 may be integrated on the same chip as the main common-gate device MCG, or it may be a separate amplifier chip attached in the same package and connected, for example, using wire bonds or other connection means (e.g., printed circuit board traces). In some embodiments, the auxiliary amplifier 404 may be implemented as an amplifier external to the packaged cascode device, with signals between the packaged cascode device and the auxiliary amplifier 404 being conveyed using input/output leads on the package. Although not explicitly shown for clarity, the amplifier circuit 400 may include a DC bias circuit for biasing the auxiliary amplifier 404 at a quiescent bias point.

In one or more embodiments, the auxiliary amplifier 404 may be implemented as a test structure with ground-signal-ground (GSG) probes, and used for early learning/feedback in the development stages of a design, or for modeling purposes. In this manner, the amplitude and/or phase of the signal provided to the gate of the common-gate device MCG can be varied, for example using external text equipment, to explore design trade-offs (e.g., more efficient/less stable or more stable/less efficient, etc.) without the need to change the physical hardware or tape-out new hardware.

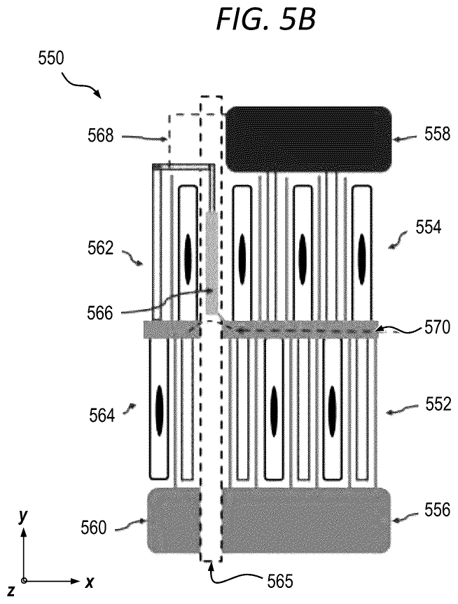

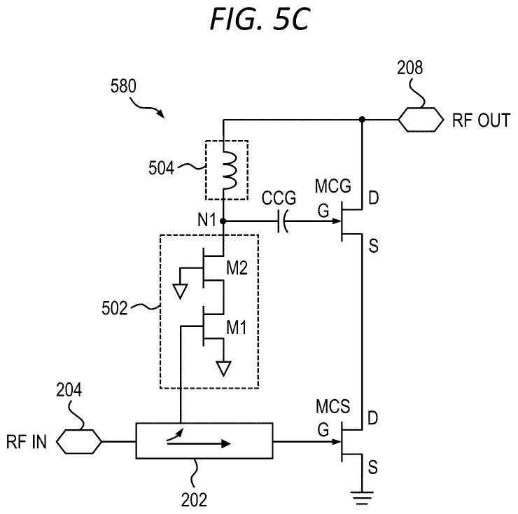

FIG. 5A is a schematic diagram depicting at least a portion of an example RF power amplifier circuit 500 with active voltage reconstruction, according to one or more embodiments of the invention. The amplifier circuit 500 may be an example implementation of the conceptual amplifier circuit topology 400 shown in FIG. 4. Referring to FIG. 5A, the amplifier circuit 500 includes an auxiliary amplifier 502 implemented using a smaller cascode transistor arrangement, compared to the primary cascode transistor arrangement including common-source device MCS and common-gate device MCG. Specifically, the auxiliary amplifier 502 includes an auxiliary common-source transistor M1 having a source connected to ground (which may be the same ground to which the common-source device MCS is connected), and a gate adapted to receive a portion of the RF input signal RF IN provided by the input power coupler 202. The auxiliary amplifier 502 further includes an auxiliary common-gate transistor M2 having a source connected to a drain of the auxiliary common-source transistor M1, a gate connected to ground, and a drain providing an output signal of the auxiliary amplifier 502. The output signal from the auxiliary amplifier 502, present at the drain of the auxiliary common-gate transistor M2, is fed to the gate of the primary common-gate transistor MCG through the second capacitor CCG.

DC biasing for the auxiliary amplifier 502 may be provided by an auxiliary amplifier DC feed (i.e., DC bias element) 504 coupled between the drain of the primary common-gate device MCG and the drain of the auxiliary common-gate device M2 for biasing the auxiliary amplifier 502 at a quiescent bias point. The auxiliary amplifier DC feed 504 may be implemented as an inductor, although embodiments are not limited thereto. The amplifier circuit 500 further includes an auxiliary to primary mid-voltage connection 506 which electrically connects the drain of the auxiliary common-source device M1 and the source of the auxiliary common-gate device M2 to the drain of the primary common-source device MCS and the source of the primary common-gate device MCG.

By way of example only and without limitation, FIG. 5B is a schematic plan view of an illustrative layout 550 of the amplifier circuit 500 shown in FIG. 5A. Referring to FIG. 5B, the layout 550 conceptually depicts the primary common-source device (MCS in FIG. 5A) 552 and the primary common-gate device (MCG in FIG. 5A) 554 adjacent the primary common-source device 552 in the first horizontal direction (y-direction). Each of the primary common-source device 552 and the primary common-gate device 554 may be formed as a multiple-fingered device.

Multiple gate fingers of the primary common-source device 552 are connected to an input gate pad 556, which may be represented by the first terminal 204 of the amplifier circuit 500 shown in FIG. 5A. The input gate pad 556 may extend longitudinally in the second horizontal direction (e.g., x-direction). Multiple drain fingers of the primary common-gate device 554 are connected to an output drain pad 558, which may be represented by the second terminal 208 of the amplifier circuit 500 shown in FIG. 5A. The output drain pad 558 may extend longitudinally in the second horizontal direction. Each of the input gate pad 556 and the output drain pad 558 may comprise metal (e.g., metallization layer). The primary common-source device 552 and the primary common-gate device 554 may be formed between the input gate pad 556 and the output drain pad 558 in the first horizontal direction. A small portion 560 of the input gate pad 556 may act as a proportional input power coupler, which may be represented by the input power coupler 202 in FIG. 5A.

The layout 550 includes an auxiliary common-gate device 562 (auxiliary common-gate device M2 in FIG. 5A), which may be implemented as a subset (i.e., one or more) of the plurality of fingers of the primary common-gate device 554. An auxiliary common-source device 564 (auxiliary common-source device M1 in FIG. 5A) may be implemented as a subset (i.e., one or more) of the plurality of fingers of the primary common-source device 552. The fingers of the auxiliary common-source device 564 and the auxiliary common-gate device 554 may represent a small percentage (e.g., about 10%) of the total plurality of fingers of the primary common-source device 552 and primary common-gate device 554. Together, the auxiliary common-gate device 562 and the auxiliary common-source device 564 may implement the auxiliary amplifier 502 of the amplifier circuit 500 shown in FIG. 5A. A small gap 565 in the transistor layout, as well as in the input gate pad 556, may be used to physically isolate the auxiliary amplifier device fingers 562, 564 from the primary common-source device 552 and primary common-gate device 554 fingers.

The layout 550 further includes a common-gate input capacitor 566, which may be represented by the second capacitor CCG in FIG. 5A. An auxiliary amplifier DC feed 568 is shown in the layout 550 for providing DC biasing of the auxiliary amplifier 562, 564. An auxiliary to primary amplifier mid-voltage connection 570 is also provided in the layout 550 for (1) electrically connecting the source of the auxiliary common-gate device 562 to the drain of the auxiliary common-source device 564 and (2) electrically connecting the multiple source fingers of the primary common-gate device 554 to the multiple drain fingers of the primary common-source device 552. The auxiliary to primary amplifier mid-voltage connection 570 may be represented by the auxiliary to primary mid-voltage connection 506 in the amplifier circuit 500 of FIG. 5A.

FIG. 5C is a schematic diagram depicting at least a portion of another example RF power amplifier circuit 580 with active voltage reconstruction for implementing the amplifier circuit topology of FIG. 4, according to another embodiment of the present invention. Referring to FIG. 5C, the amplifier circuit 580 is essentially the same as the amplifier circuit 500 shown in FIG. 5A, except that the amplifier circuit 580 does not include the auxiliary to primary mid-voltage connection 506, and thus represents a slight variation of the amplifier circuit 500 shown in FIG. 5A. In the amplifier circuit 580, the voltage present at the junction of the drain of the auxiliary common-source device M1 and the source of the common-gate device M2 will be independent of the voltage present at the junction of the drain of the primary common-source device MCS and the source of the primary common-gate device MCG.

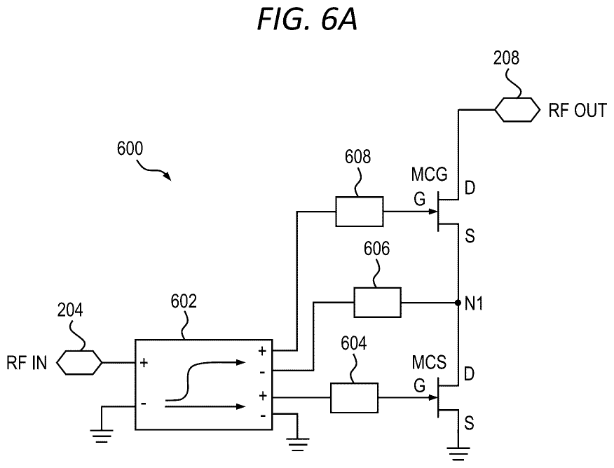

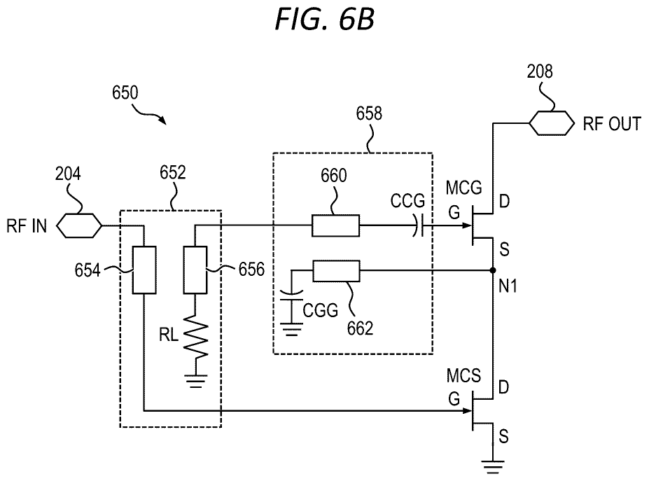

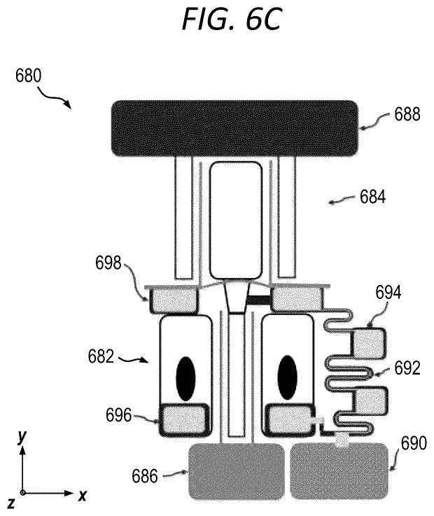

FIG. 6A is a schematic diagram conceptually depicting at least a portion of an example power RF cascode amplifier circuit 600 utilizing a power input coupler with independent grounds, according to one or more embodiments of the invention. Referring to FIG. 6A, the amplifier circuit 600 includes a differential input power coupler (i.e., differential power divider) 602. Unlike the singled-ended (i.e., unbalanced) input power coupler 202 used in the amplifier circuit 500 of FIG. 5A, the input power coupler 602 is implemented as a balun, so that a differential output signal, with independent signal and independent ground ports, can be fed to the input of the common-gate device MCG. In one or more embodiments, the differential input power coupler 602 may incorporate isolation between the output ports. In other embodiments, the differential input power coupler 602 may not incorporate isolation between the output ports.

The amplifier circuit 600 may include impedance/voltage transformation networks coupled to the output ports of the differential input power coupler 602. Specifically, a first impedance/voltage transformation network 604 may be coupled between a first output signal port (+) of the differential input power coupler 602 and the gate of the common-source device MCS. A first output ground port (−) of the differential input power coupler 602 may be connected to ground. A second impedance/voltage transformation network 606 may be coupled between a second output ground port (−) of the differential input power coupler 602 and the mid-voltage node N1 connecting the drain of the common-source device MCS and the source of the common-gate device MCG. The mid-voltage node N1 may be considered a ground for common-gate device MCG. A third impedance/voltage transformation network 608 may be coupled between a second output signal port (+) of the differential input power coupler 602 and the gate of the common-gate device MCG. The second and third impedance/voltage transformation networks 606, 608 coupled to the gate and source, respectively, of the common-gate device MCG may include DC decoupling configured to prevent a DC short between the mid-voltage node N1 and the RF input port.

By delivering a balanced signal to the gate of the common-gate device MCG, the signal supplied by the differential input power coupler 602 only needs to have, for example, a ±2 V swing, which is considerably more controllable than a signal having a ±47 V swing if considered as a single-ended signal with reference to ideal ground. The differential signal at the gate of the common-gate device MCG essentially rides on the voltage swing already present at the source of the common-gate device MCG. This circuit topology provides enhanced stability and performance for the cascode device at high frequency.

In one or more embodiments, the first impedance/voltage transformation network 604 may be incorporated into the design or layout of the differential input power coupler 602, and the second and third impedance/voltage transformation networks 606, 608 may be incorporated onto the same chip as the cascode transistor. The combination of the differential input power coupler 602 and the first impedance/voltage transformation network 604 may be implemented in the layout as a 90-degree hybrid coupler, such as, for example, a branch-line coupler, coupled transmission line coupler, Lange coupler or Wilkinson splitter with 90-degree phase line. The second and third impedance/voltage transformation networks 606, 608 may be implemented as a broadside coupled transmission line pair or edge-side coupled transmission line pair, and may be integrated onto the same chip as the common-gate device MCG.

FIG. 6B is a schematic diagram depicting at least a portion of an example power RF cascode amplifier circuit 650 for implementing the illustrative amplifier circuit 600 of FIG. 6A. With reference to FIG. 6B, the differential input power coupler (602 in FIG. 6A) may be implemented as a 90-degree (3 dB) coupled line hybrid coupler 652, in one or more embodiments. The coupled line hybrid coupler 652 is a four-port device (a common port, an isolated port, and two coupled ports) configured to split a portion of the RF input signal RF IN with a resultant 90-degree phase difference between output ports, while maintaining high isolation between the ports. Coupled line couplers (e.g., Lange coupler) are not “DC connected,” unlike direct-coupled couplers such as Wilkinson and branch-line couplers. The coupled line hybrid coupler 652 includes a first transmission line 654 and a second transmission line 656, the first and second transmission lines 654, 656 being close enough in proximity so that energy from one transmission line passes to the other transmission line. The first transmission line 654 is connected between the first terminal 204, for receiving the RF input signal RF IN, and the gate of the common-source device MCS. The second transmission line 656 is connected between a coupled line balun 658 and ground through a termination resistor RL.

The coupled line balun 658, which is configured to establish a balanced input signal fed to the common-gate device MCG (with the common-gate device MCG source as a ground), includes a first transmission line 660 and a second transmission line 662, the first and second transmission lines 660, 662 being close enough in proximity so that energy from one transmission line passes to the other transmission line. The first transmission line 660 of the coupled line balun 658 may be connected between the isolated second transmission line 656 of the coupled line hybrid coupler 652 and the gate of the common-gate device MCG through the second capacitor CCG. The second transmission line 662 of the coupled line balun 658 may be connected between the mid-voltage node N1 and ground through the third capacitor CGG. In some embodiments, the second capacitor CCG and the third capacitor CGG may be incorporated in the coupled line balun 658, although embodiments are not limited thereto. Additionally, the characteristic impedance of the first and second transmission lines 660, 662 in the coupled line balun 658 and/or the first and second transmission lines 654, 656 in the coupled line hybrid coupler 652 may be configured to increase the input impedance of the combined cascode device (including the common-source device MCS and the common-gate device MCG) while maintaining good bandwidth (e.g., a gain flatness of less than about 1.5 dB across a wider bandwidth); that is, it can be used as part of a pre-match.

Some of the matching from the input of the power RF cascode amplifier die to a 50-ohm port (for a customer) may be done in the packaged product or on the die. This may be referred to as “pre-match,” but this will typically not precisely match the desired 50-ohm impedance. External to the power RF cascode amplifier die, there may be additional impedance matching elements to match the input and output of the power RF cascode amplifier die to the desired 50 ohms. If the matching is done, with a good transformation ratio, then a relatively wide bandwidth may be achieved. By way of example only and without limitation, consider a power RF cascode amplifier die wherein the input impedance of the common-source device MCS is about 0.1 ohms. Attempting to match from 0.1 ohms to a desired 50 ohms in one stage would result in a very narrow bandwidth. However, if pre-matching is used to match the input impedance from 0.1 ohms to 2 ohms, and an external (i.e., off-chip) PCB impedance matching network is used to bring the input impedance from 2 ohms to 50 ohms, then overall gain, efficiency and power of the power RF cascode amplifier can be substantially flat over a wider bandwidth.

At least a portion of the second and third impedance/voltage transformation networks 606, 608 in the illustrative amplifier circuit 600 of FIG. 6A may be implemented as part of, and/or integrated with, the coupled line balun 658. In one or more embodiments, the coupled line hybrid coupler 652 and the coupled line balun 658 (or at least portions thereof) may be integrated into the differential input power coupler 602 in the amplifier circuit 600 of FIG. 6A.

By way of example only and without limitation, FIG. 6C is a schematic plan view of an illustrative layout 680 of the power RF cascode amplifier circuit 650 shown in FIG. 6B, according to one or more embodiments. The illustrative layout 680 may represent a narrow section (e.g., two gate fingers) of an overall cascode cell of the amplifier circuit 650 shown in FIG. 6B using broad-side coupled lines. It is to be appreciated, however, that embodiments of the invention are not limited to any specific layout.

Referring to FIG. 6C, the layout 680 conceptually depicts the common-source device (MCS in FIG. 6B) 682 and the common-gate device (MCG in FIG. 6B) 684 adjacent the common-source device 682 in the first horizontal direction (y-direction). Each of the common-source device 682 and the common-gate device 684 may be formed as a multiple-fingered device. Multiple gate fingers of the common-source device 682 are connected to an input gate pad 686, which may be represented by the first terminal 204 of the amplifier circuit 650 shown in FIG. 6B. The input gate pad 686 may extend longitudinally in the second horizontal direction (e.g., x-direction). Multiple drain fingers of the common-gate device 684 may be connected to an output drain pad 688, which may be represented by the second terminal 208 of the amplifier circuit 650 shown in FIG. 6B. The output drain pad 688 may extend longitudinally in the second horizontal direction. Each of the input gate pad 686 and the output drain pad 688 may comprise metal (e.g., metallization layer). The common-source device 682 and the common-gate device 684 may be formed between the input gate pad 686 and the output drain pad 688 in the first horizontal direction.

In the illustrative layout 680, the coupled line balun (658 in the amplifier circuit 650 of FIG. 6B) is integrated onto the same chip as the cascode device and the coupled line hybrid coupler (652 in the amplifier circuit 650 of FIG. 6B) is external to the chip, although embodiments are not limited to this layout arrangement. A separate common-gate input pad 690 is employed to receive the RF signal from the external coupled line hybrid coupler and to feed the received RF signal to the coupled line balun. The common-gate input pad 690 may be formed of metal, such as, for example, using the same metallization layer as used to form the input gate pad 686 and/or the output drain pad 688.

In one or more embodiments, the balun may be implemented using broadside coupled lines, which may comprise, for example, a first metal layer and a second metal layer in a standard SiC or GaN process. To minimize size, the balun may be implemented with one or more alternating coupled line inductive sections 692 and coupled line capacitive section 694. The first and second metal layers used for the coupled lines of the balun can be the same first and second metal layers used to implement a metal-insulator-metal (MIM) capacitor in the fabrication process. The third capacitor CGG 696, which may be incorporated into the balun, can be grounded to the back of the chip with through-substrate vias (TSVs), but the reference plane for the second capacitor CCG 698 will be connected to the drain of the common-source device MCS 682, which is also the source of the common-gate device MCG 684 (node N1 in FIG. 6B). In one or more embodiments, the input coupled line hybrid coupler (652 in FIG. 6B) may be implemented on a separate chip attached in the same package, or as part of an input pre-match network in the packaged cascode device.

It will be understood that, although ordinal terms such as first, second, etc., may be used herein to describe various elements, these elements should not be limited by such terms. These terms are only used to distinguish one element from another. For example, a first element could be termed a second element, and, similarly, a second element could be termed a first element, without departing from the scope of the present disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as may be used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below,” “above,” “upper,” “lower,” “horizontal,” “lateral,” and/or “vertical,” may be used herein to describe a relationship of one element, layer or region to another element, layer or region as illustrated in the figures. It will be understood, however, that these terms are intended to encompass different orientations of the device in place of or in addition to the orientation depicted in the figures.

In the drawings and specification, there have been disclosed typical embodiments of the invention and, although specific terms are employed, they are used in a generic and descriptive sense only and not for purposes of limitation, the scope of the invention being set forth in the following claims.

1. A cascode amplifier circuit, comprising:
a first transistor connected in a common-source configuration, the first transistor comprising a gate for receiving a radio frequency (RF) input signal; and
a second transistor connected in a common-gate configuration, the second transistor comprising a first source/drain for delivering an RF output signal of the cascode amplifier circuit, a second source/drain connected to a first source/drain of the first transistor, and a gate for receiving a portion of the RF input signal.

2. The cascode amplifier circuit of claim 1, further comprising an input power coupler connected to the gate of the first transistor, the input power coupler being configured to feed a portion of the RF input signal provided to the second transistor.

3. The cascode amplifier circuit of claim 2, further comprising an impedance/voltage transform network connected to the gate of the second transistor, the impedance/voltage transform network being configured to transform the portion of the RF input signal supplied by the input power coupler to a prescribed voltage level, impedance and/or phase.

4. The cascode amplifier circuit of claim 1, further comprising an impedance/voltage transform network connected to the gate of the second transistor, the impedance/voltage transform network being configured to transform the portion of the RF input signal to a prescribed voltage level, impedance and/or phase.

5. The cascode amplifier circuit of claim 1, further comprising:
a first capacitor connected between the gate of the second transistor and the first source/drain of the second transistor;
a second capacitor connected between the gate of the second transistor and ground; and
a third capacitor connected between the gate of the second transistor and the gate of the first transistor,
wherein the first transistor includes a first source/drain connected to the second source/drain of the second transistor, and a second source/drain connected to ground.

6. The cascode amplifier circuit of claim 1, further comprising an auxiliary amplifier including an input for receiving the portion of the RF input signal and an output connected to the gate of the second transistor, the auxiliary amplifier being configured to condition the portion of the RF input signal to generate a conditioned input signal provided to the gate of the second transistor.

7. The cascode amplifier circuit of claim 6, wherein each of the first and second transistors comprises a plurality of fingers, and wherein the auxiliary amplifier comprises a portion of the plurality of fingers of each of the first and second transistors.

8. The cascode amplifier circuit of claim 6, wherein the auxiliary amplifier comprises:
a third transistor including a first source/drain connected to ground and a gate for receiving the portion of the RF input signal; and
a fourth transistor including a first source/drain connected to a second source/drain of the third transistor, a second source/drain connected to the gate of the second transistor, and a gate connected to ground.

9. The cascode amplifier circuit of claim 8, wherein the second source/drain of the third transistor is connected to the first source/drain of the first transistor.

10. The cascode amplifier circuit of claim 1, further comprising a differential input power coupler, the differential input power coupler comprising a differential input port configured to receive the RF input signal, a first output signal port connected to the gate of the first transistor, a first output ground port connected to ground, a second output signal port connected to the gate of the second transistor, and a second output ground port connected to the second source/drain of the second transistor and the first source/drain of the first transistor.

11. The cascode amplifier circuit of claim 10, further comprising:
a first impedance/voltage transformation network connected between the first output signal port of the differential input power coupler and the gate of the first transistor;
a second impedance/voltage transformation network connected between the second output ground port of the differential input power coupler and mid-voltage node connecting the second source/drain of the second transistor and the first source/drain of the first transistor; and
a third impedance/voltage transformation network connected between the second output signal port and the gate of the second transistor.

12. The cascode amplifier circuit of claim 1, further comprising:
a coupled line hybrid coupler, the coupled line hybrid coupler comprising an input port for receiving the RF input signal, a first output port for providing the RF input signal to the gate of the first transistor, and a second output port for providing the portion of the RF input signal to the gate of the second transistor, the RF input signal provided at the first output port of the coupled line hybrid coupler having a prescribed phase difference relative to the portion of the RF input signal provided at the second output port of the coupled line hybrid coupler; and
a coupled line balun, the coupled line balun comprising an input port connected to the second output port of the coupled line hybrid coupler, a first output port connected to the second source/drain of the second transistor, and a second output port connected to the gate of the second transistor.

13. A cascode amplifier circuit, comprising:
a first transistor comprising a first source/drain connected to ground, a gate connected to an input terminal, and a second source/drain;
a second transistor comprising a first source/drain connected to the second source/drain of the first transistor, a second source/drain connected to an output terminal, and a gate;
a first capacitor connected between the second source/drain and gate of the second transistor; and
a second capacitor connected between the gate of the second transistor and the gate of the first transistor,
wherein the gate of the second transistor is coupled to ground through a series resistor-capacitor network.

14. The amplifier circuit of claim 13, wherein the series RC network comprises:
a first resistor having a first terminal connected to ground; and
a third capacitor having a first terminal connected to the gate of the second transistor and a second terminal connected to a second terminal of the first resistor.

15. The amplifier circuit of claim 14, further comprising a second resistor connected between the gate of the first transistor and the input terminal.

16. The amplifier circuit of claim 13, wherein each of the first and second transistors comprises a high-electron-mobility transistor.

17. The amplifier circuit of claim 13, wherein each of the first and second transistors comprises a gallium nitride high-electron-mobility transistor on a silicon carbide or silicon substrate.

18. (canceled)

19. A cascode amplifier circuit, comprising:
a first transistor comprising a first source/drain connected to ground, a gate connected to an input terminal, and a second source/drain;
a second transistor comprising a first source/drain connected to the second source/drain of the first transistor, a second source/drain connected to an output terminal, and a gate;
a power coupler comprising an input port connected to the input terminal, a first output port connected to the gate of the first transistor, and a second output port connected to the gate of the second transistor, the power coupler being configured to provide a first signal at the first output port and a second signal at the second output port, the first and second signals being respective portions of an input signal present at the input port; and
an auxiliary amplifier having an input connected to the second output port of the power coupler and having an output connected to the gate of the second transistor.

20. The amplifier circuit of claim 19, further comprising a capacitor connected between the output of the auxiliary amplifier and the gate of the second transistor.

21. The amplifier circuit of claim 19, wherein the auxiliary amplifier comprises:
a third transistor including a first source/drain connected to ground, a gate connected to the second output port of the power coupler, and a second source/drain; and
a fourth transistor including a first source/drain connected to the second source/drain of the third transistor, a second source/drain connected to the gate of the second transistor, and a gate connected to ground.

22.-31. (canceled)
